(19) United States
(12) Patent Application Publication
(10) Pub. No.: US 2024/0332270 A1
(43) Pub. Date: Oct. 3, 2024

(54) SEMICONDUCTOR PACKAGE WITH DECOUPLING CAPACITOR AND METHOD FOR MANUFACTURING THE SAME

(71) Applicant: SAMSUNG ELECTRONICS CO., LTD., Suwon-si (KR)

(72) Inventors: Sangjin Baek, Suwon-si (KR); Kyung Don Mun, Suwon-si (KR); Ji Hwang Kim, Suwon-si (KR); Kyoung Lim Suk, Suwon-si (KR)

(21) Appl. No.: 18/475,863

(22) Filed: Sep. 27, 2023

(30) Foreign Application Priority Data
Mar. 30, 2023 (KR) 10-2023-0042071

(51) Int. Cl. H01L 25/16; H01L 21/56; H01L 23/00; H01L 23/31

(52) U.S. Cl. CPC H01L 25/16; H01L 21/56; H01L 23/3128; H01L 24/06; H01L 24/08; H01L 24/16; H01L 24/80; H01L 24/81; H01L 28/40; H01L 2224/06181; H01L 2224/08145; H01L 2224/16145; H01L 2224/16227; H01L 2224/80895; H01L 2224/80896; H01L 2224/81801

(57) ABSTRACT

The present disclosure relates to semiconductor packages and methods for manufacturing semiconductor packages. An example semiconductor package includes a top die, first and second bottom dies attached on a lower surface of the top die and being apart from each other by a preset distance, and at least one decoupling capacitor connected to the lower surface of the top die between the first bottom die and the second bottom die. The top die, the first bottom die, and the second bottom die are chiplets.

### CROSS-REFERENCE TO RELATED APPLICATION

This application claims priority to and the benefit of Korean Patent Application No. 10-2023-0042071 filed in the Korean Intellectual Property Office on Mar. 30, 2023, the entire contents of which is incorporated herein by reference.

### BACKGROUND

### (a) Technical Field

The present disclosure relates to a semiconductor package with a decoupling capacitor and a method for manufacturing the same.

### (b) Description of the Related Art

The density of semiconductor devices increases, the operating speed increases, and the size of semiconductors decreases. Accordingly, the current consumption increases, the transition time is shortened, and the noise margin is reduced. The increased current causes an ohmic voltage drop, which adversely affects the power integrity of the semiconductor chip.

To solve this, a decoupling capacitor needs to be connected in parallel to the power network. The decoupling capacitor removes the radio frequency energy entering the power network and lowers the peak of the current surge. The use of a decoupling capacitor is more effective than other methods for securing reliability of a power network or controlling noise.

Therefore, it is necessary to connect a decoupling capacitor to the semiconductor device including an active element. FIG. 1 shows the available locations of a decoupling capacitor within a semiconductor package. Decoupling capacitors need not be provided at all positions shown in FIG. 1.

The semiconductor package includes a semiconductor die 100, a redistribution layer 200, and a substrate 300. The semiconductor die 100 and the redistribution layer 200 are electrically connected through a plurality of solder bumps B3. The redistribution layer 200 and the substrate 300 are electrically connected through a plurality of solder bumps B2. A plurality of solder balls B1 are disposed on the lower surface of the substrate 300.

The semiconductor package shown in FIG. 1 has a typical structure. Decoupling capacitors C1, C2, C3, C4, C5 and C6 are shown to show possible placement of the decoupling capacitors.

The decoupling capacitor C1 is attached to the lower surface of the substrate. The decoupling capacitor C2 is embedded inside the substrate. The decoupling capacitor C3 is attached to the upper surface of the substrate. The decoupling capacitor C4 is attached to the lower surface of the redistribution layer 200. The decoupling capacitor C5 is embedded inside the redistribution layer 200. The decoupling capacitor C6 is attached to the upper surface of the redistribution layer 200.

The power network includes a power supply line PWR and a ground line GND. The decoupling capacitor is connected in parallel to the power supply line and the ground line.

In FIG. 1, power is supplied to the semiconductor die 100 through a power network. The decoupling capacitors C1, C2, and C3 have relatively sufficient placement spaces, but paths to the semiconductor die 100 are relatively long. Decoupling capacitors C4, C5 and C6 have relatively short paths. However, as described above, as operating speeds increase and device densities increase, the decoupling capacitors need to be located closer to the semiconductor die 100.

In FIG. 1, attaching a decoupling capacitor on the lower surface of the semiconductor die 100 may be considered. However, micro bumps or Cu pillars are widely used between the semiconductor die 100 and the redistribution layer 200, and a space for attaching decoupling capacitors is very limited. Moreover, if decoupling capacitors are attached on the lower surface of the semiconductor die 100, the number of solder bumps B3 is reduced. When the number of solder bumps B3 is reduced, the number of input/output paths of the semiconductor die 100 is limited.

### SUMMARY

The present disclosure relates to a new location of a decoupling capacitor that is close to an active element and does not limit the number of input/output paths, by utilizing chiplet technology.

In some aspects, a semiconductor package includes a top die, first and second bottom dies attached on a lower surface of the top die and being apart from each other by a preset distance, and at least one decoupling capacitor connected to the lower surface of the top die between the first bottom die and the second bottom die, where the top die, the first bottom die, and the second bottom die are chiplets.

In some aspects, a method for manufacturing a semiconductor package includes attaching at least one decoupling capacitor on a lower surface of a top die, attaching a first bottom die and a second bottom die having a plurality of solder bumps on lower surfaces onto a carrier, where the first bottom die and the second bottom die are spaced apart from each other with a preset gap, attaching the top die on upper surfaces of first and second bottom dies by a hybrid bonding such that the at least one decoupling capacitor is positioned in the gap between the first bottom die and the second bottom die, sealing all components on the carrier by a mold material, and grinding the mold material to expose a surface of the top die and removing the carrier, where the top die, the first bottom die, and the second bottom die may be chiplets, and where a portion of upper surfaces of the first bottom die and the second bottom die may face the top die and a remaining portion may extend outwards on a plane of the top die.

In other aspects, a method for manufacturing a semiconductor package includes attaching at least one decoupling capacitor on a lower surface of a top die, attaching upper surfaces of first bottom die and a second bottom die on the lower surface of the top die by a hybrid bonding, where the at least one decoupling capacitor is positioned between the first bottom die and the second bottom die, sealing all components on the lower surface of the top die by a mold material, and grinding the mold material to expose lower surfaces of the first bottom die and the second bottom die, and providing a plurality of solder bumps on the lower surfaces of the first bottom die and the second bottom die, where the top die, the first bottom die, and the second bottom die may be chiplets, and where entire upper surfaces of the first bottom die and the second bottom die may face the top die.

In some implementations of the present disclosure, in a semiconductor package employing a chiplet, since the decoupling capacitor is attached on the lower surface of the top die, the decoupling capacitor is located closer to the active element.

In addition, since two or more bottom dies are spaced apart from each other by a predetermined distance on the lower surface of the top die, and a decoupling capacitor is disposed between the two or more bottom dies, the overall size of the semiconductor package including the decoupling capacitor may be kept small.

### BRIEF DESCRIPTION OF THE DRAWINGS

FIG. 1 shows available locations of a decoupling capacitor within a semiconductor package.

FIG. 2 is a schematic cross-sectional view of an example of a semiconductor package.

FIG. 3 is a schematic cross-sectional view of another example of a semiconductor package.

FIG. 4 is a schematic cross-sectional view of another example of a semiconductor package.

FIG. 5 is a schematic cross-sectional view of another example of a semiconductor package.

FIG. 6 is a schematic cross-sectional view of another example of a semiconductor package.

FIG. 7 is a schematic cross-sectional view of another example of a semiconductor package.

FIG. 8 is a schematic top plan view of an example of a semiconductor package.

FIG. 9 is a schematic top plan view of another example of a semiconductor package.

FIG. 10 is a schematic top plan view of another example of a semiconductor package.

FIG. 11A to FIG. 11G show an example of a method for manufacturing a semiconductor package, respectively.

FIG. 12A to FIG. 12G show another example of a method for manufacturing a semiconductor package, respectively.

FIG. 13 is a top plan view of an example of a semiconductor package with a plurality of decoupling capacitors.

FIG. 14 is a top plan view of another example of a semiconductor package with a plurality of decoupling capacitors.

FIG. 15 is a top plan view of another example of a semiconductor package with a plurality of decoupling capacitors.

### DETAILED DESCRIPTION

The above and other aspects, features, and advantages of the present disclosure will be described more fully hereinafter with reference to the accompanying drawings, in which some implementations of the disclosure are shown. As those skilled in the art would realize, the described implementations may be modified in various different ways, all without departing from the spirit or scope of the present disclosure.

In order to clearly describe the present disclosure, parts or portions that are irrelevant to the description are omitted, and identical or similar components throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

In addition, in the drawing, bumps, metal pads, and vias may be enlarged and exaggerated compared to other elements to better show their structures.

It will be understood that when an element such as a layer, film, region, area or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “include” and variations such as “includes” or “including” will be understood to imply the inclusion of stated elements but not the exclusion of any other elements.

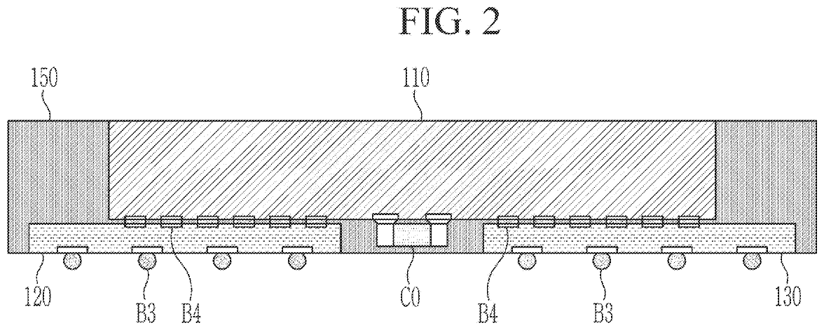

Hereinafter, various implementations of a semiconductor package according to the present disclosure will be described with reference to FIGS. 2 to 10, but the protection scope of the present disclosure is not limited to these implementations.

FIG. 2 is a schematic cross-sectional view of an example of a semiconductor package. A semiconductor package in some implementations includes a top die 110, a first bottom die 120, a second bottom die 130, a decoupling capacitor C0, a mold 150, and a plurality of solder bumps B3.

The top die 110, the first bottom die 120 and the second bottom die 130 are chiplets. Chiplets are distinguished from monolithic, which integrates multiple functions such as CPU, modem, DDR, and GPU into a single chip. The chiplet technology is a technology that separates various functions of existing semiconductor chips into several chips. Adoption of chiplets improves yield and facilitates efficient development. Unlike monolithic, in which the entire chip must be redesigned in order to upgrade one of several functions included in one chip, only the chip corresponding to that function needs to be upgraded in the chiplet technology.

The present disclosure proposes a new position of the decoupling capacitor different from various positions previously proposed. The present disclosure applies chiplets, to divide an existing semiconductor die into several dies (chiplets), and defines a space for a decoupling capacitor when the multiple dies (chiplets) are bonded to each other.

As shown in FIG. 2, a decoupling capacitor is attached on a lower surface of the top die 110. The first bottom die 120 and the second bottom die 130 are also attached to the lower surface of the top die 110. The first bottom die 120 and the second bottom die 130 are spaced apart from each other by a preset distance. The decoupling capacitor C0 is attached to a space between the first bottom die 120 and the second bottom die 130.

The decoupling capacitor C0 has various sizes and shapes. The decoupling capacitor C0 may be determined according to specifications of a semiconductor package. The first bottom die 120 and the second bottom die 130 may be spaced apart from each other by a space necessary for attaching the determined decoupling capacitor C0.

In some implementations, the top die 110 and the first and second bottom dies 120 and 130 may be bonded by hybrid bonding B4. The hybrid bonding B4 may be more suitable for higher density connection terminals than bonding using solder bumps. However, the present disclosure is not limited thereto, and the top die 110 and the first and second bottom dies 120 and 130 may be bonded using micro bumps.

The plurality of solder bumps B3 are provided on lower surfaces of the first bottom die 120 and the second bottom die 130. The plurality of solder bumps B3 are used to electrically connect the semiconductor package to the redistribution layer or the like.

The semiconductor package includes the mold 150. The mold 150 surrounds lateral sides of the top die 110, and covers the decoupling capacitor C0. In the present example, a portion of upper surfaces of the first and second bottom dies 120 and 130 face the top die 110 and a remaining portion thereof extends outward on a plane of the top die 110 and is exposed upward. Therefore, the mold 150 covers the exposed upper surfaces of the first and second bottom dies 120 and 130.

In FIG. 2, the decoupling capacitor C0 is disposed at a center of the lower surface of the top die 110. In this case, the decoupling capacitor C0 may be connected to any location in the top die 110 through the shortest path. However, the present disclosure is not limited thereto. The decoupling capacitor C0 may be located anywhere on the lower surface of the top die 110. The location of the decoupling capacitor C0 may be determined in consideration of miniaturization of the semiconductor package according to the number, size, and arrangement of bottom dies.

In some implementations, the top die 110 may be a logic die, and the first and second bottom dies 120 and 130 may be I/O (input and output) dies. However, since division into multiple dies is a design matter when chiplets are applied, the number and/or size of the dies may be determined according to design requirements.

Although not shown, the first and second bottom dies 120 and 130 may include through-silicon vias (TSV). The top die 110 may pass through the first and second bottom dies 120 and 130 through the through-silicon vias and be connected to the outside through the solder bump B3.

In the present example, the two bottom dies 120 and 130 are attached to the lower surface of the top die 110, and the two bottom dies 120 and 130 are structured to protrude outward from the top die 110 in the plan view

However, those skilled in the art will easily understand that the location of the decoupling capacitor C0 may be appropriately modified according to the number or size of the upper and bottom dies.

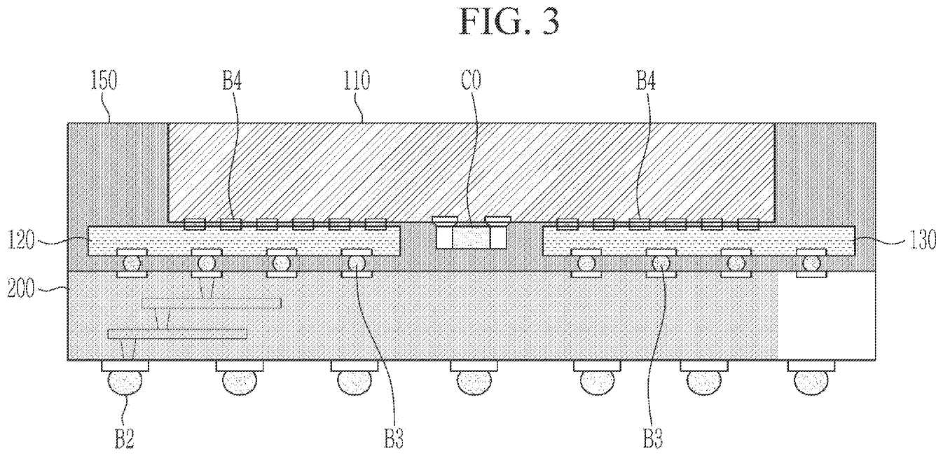

FIG. 3 is a schematic cross-sectional view of another example of a semiconductor package. FIG. 3 shows a semiconductor package having a structure in which a redistribution layer 200 is added to the semiconductor package shown in FIG. 2.

In the present example, semiconductor package includes the top die 110, the first bottom die 120, the second bottom die 130, the decoupling capacitor C0, the mold 150, and the redistribution layer 200.

The top die 110 and the first and second bottom dies 120 and 130 are bonded to each other by the hybrid bonding B4. However, they are not limited thereto and may be bonded by solder bumps such as micro bumps.

The first and second bottom dies 120 and 130 are bonded to the redistribution layer 200 through the plurality of solder bumps B3. A plurality of solder bumps B2 are disposed on a lower surface of the redistribution layer 200.

After bonding the semiconductor package shown in FIG. 2 onto the redistribution layer 200, additional molding is performed by providing a mold material between the first and second bottom dies 120 and 130 and the redistribution layer 200. The mold 150 encapsulates all components on an upper surface of the redistribution layer 200.

The top die 110, the first bottom die 120, for the second bottom die 130 and the decoupling capacitor C0, the description for the semiconductor package shown in FIG. 2 may be referred to, and repeated description is not included here again.

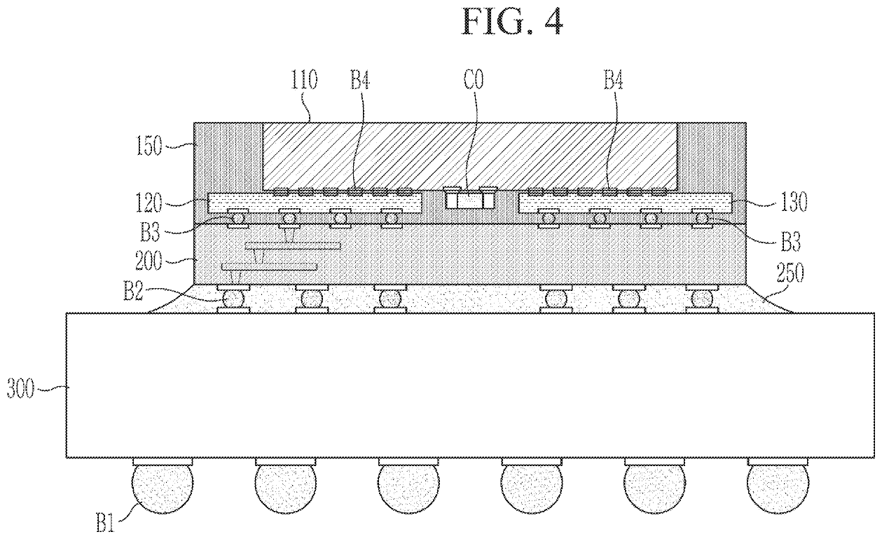

FIG. 4 is a schematic cross-sectional view of another example of a semiconductor package. FIG. 4 shows a semiconductor package having a structure in which a substrate 300 is added to the semiconductor package shown in FIG. 3.

In the present example, the semiconductor package includes the top die 110, the first bottom die 120, the second bottom die 130, the decoupling capacitor C0, the mold 150, the redistribution layer 200, and the substrate 300.

The top die 110 and the first and second bottom dies 120 and 130 are bonded to each other by the hybrid bonding B4. However, they are not limited thereto and may be bonded by solder bumps such as micro bumps.

The first and second bottom dies 120 and 130 are bonded to the redistribution layer 200 through the plurality of solder bumps B3. The redistribution layer 200 is bonded to the substrate 300 through the plurality of solder bumps B2. A plurality of solder balls B1 are disposed on a lower surface of the substrate 300.

A gap between the redistribution layer 200 and the substrate 300 is filled by an under-fill 250. The underfill 250 secures insulation of the plurality of solder bumps B2 and reinforces bonding strength between the redistribution layer 200 and the substrate 300.

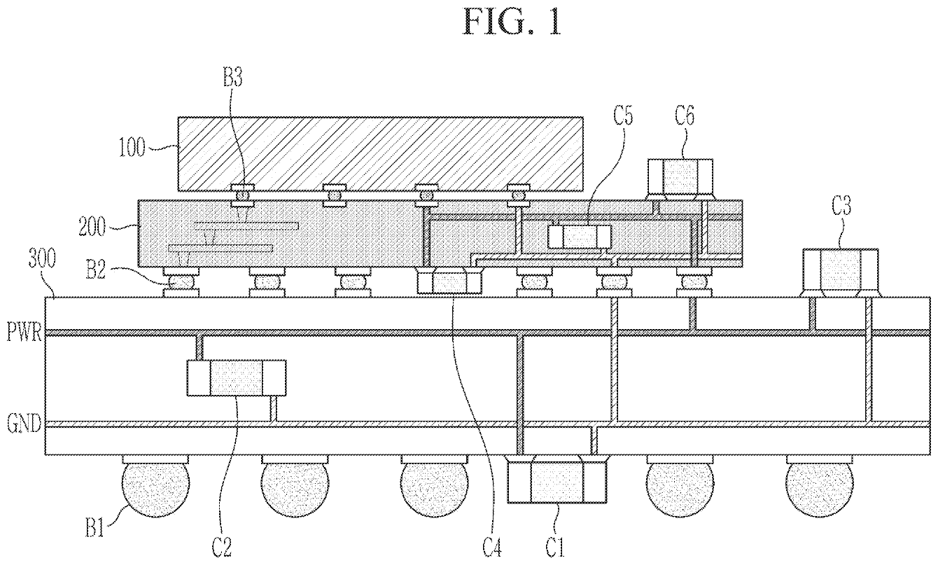

Although not shown, a decoupling capacitor may be additionally provided at one or more of the various locations shown in FIG. 1.

Also, although not shown, a power network may be provided over the substrate 300, the redistribution layer 200, the first and second bottom dies 120 and 130, and the top die 110. The decoupling capacitor C0 is connected in parallel to this the power network.

The top die 110, for the first bottom die 120, the second bottom die 130, the decoupling capacitor C0, and the redistribution layer 200, the description for the semiconductor package shown in FIG. 3 may be referred to, and repeated description is not included here again.

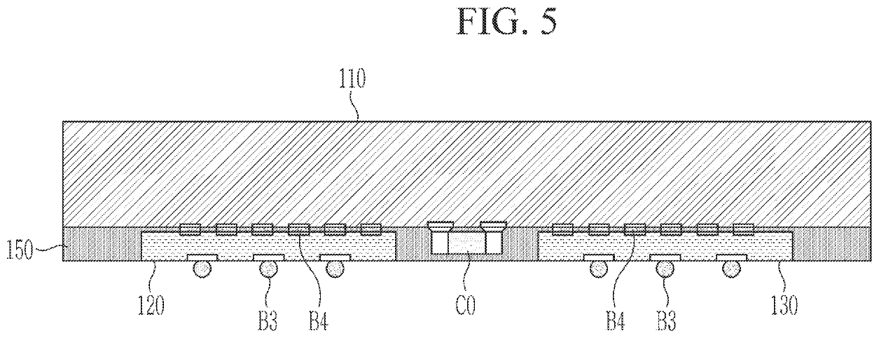

FIG. 5 is a schematic cross-sectional view of another example of a semiconductor package.

A semiconductor package in some implementations may be compared with the semiconductor package shown in FIG. 2.

Referring to FIG. 5, the semiconductor package includes the top die 110, the first bottom die 120, the second bottom die 130, and the decoupling capacitor C0. Compared with the semiconductor package shown in FIG. 2, the types of components are the same, but the first bottom die 120 and the second bottom die 130 entirely face the top die 110 on a plane. That is, the top die 110 is larger than the first and second bottom dies 120 and 130, in the plan view.

The decoupling capacitor C0 may be disposed on the lower surface of the top die 110, and disposed between the first bottom die 120 and the second bottom die 130. However, since the sizes of the first and second bottom dies 120 and 130 are smaller than that of the top die 110, it is relatively easy to secure a space for attaching the decoupling capacitor C0. That is, the decoupling capacitor C0 may be disposed in a region other than the center of the top die 110.

Since the top die 110 is relatively large, the mold 150 covers lateral sides of the first and second bottom dies 120 and 130 and also covers the decoupling capacitor C0. The lower surface of the first and second bottom dies 120 and 130 are exposed, and the plurality of solder bumps B3 are disposed on the lower surface of the first and second bottom dies 120 and 130.

The top die 110 and the first and second bottom dies 120 and 130 are bonded by the hybrid bonding B4, but is not limited thereto.

In some implementations, the top die 110 may be a logic die, and the first and second bottom dies 120 and 130 may be I/O (input and output) dies. However, since division into multiple dies is a design matter when chiplets are applied, the number and/or size of the dies may be determined according to design requirements.

Although not shown, the first and second bottom dies 120 and 130 may include TSV. The top die 110 may pass through the first and second bottom dies 120 and 130 through the through-silicon vias and be connected to the outside through the solder bump B3.

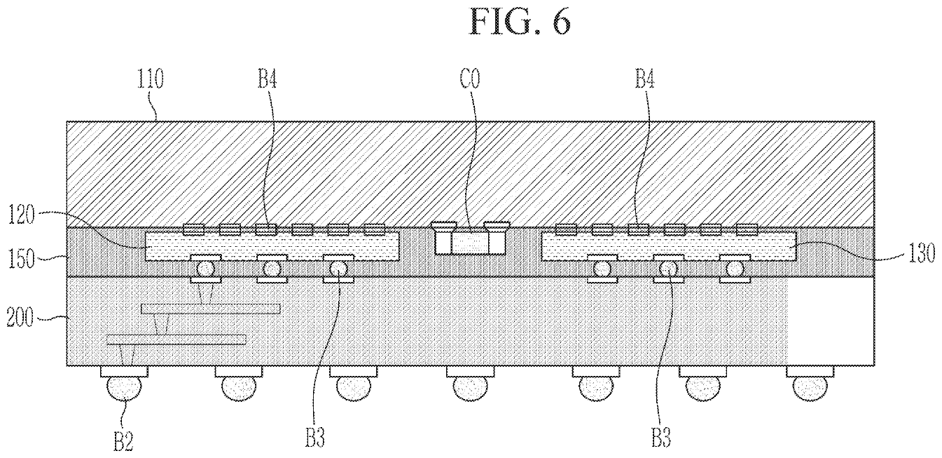

FIG. 6 is a schematic cross-sectional view of another example of a semiconductor package. FIG. 6 shows a semiconductor package having a structure in which a redistribution layer 200 is added to the semiconductor package shown in FIG. 5.

In the present example, the semiconductor package includes the top die 110, the first bottom die 120, the second bottom die 130, the decoupling capacitor C0, the mold 150, and the redistribution layer 200.

The top die 110 and the first and second bottom dies 120 and 130 are bonded to each other by the hybrid bonding B4. However, they are not limited thereto and may be bonded by solder bumps such as micro bumps.

The first and second bottom dies 120 and 130 are bonded to the redistribution layer 200 through the plurality of solder bumps B3. The plurality of solder bumps B2 are disposed on the lower surface of the redistribution layer 200.

After bonding the semiconductor package shown in FIG. 5 onto the redistribution layer 200, additional molding is performed by implanting a mold material between the first and second bottom dies 120 and 130 and the redistribution layer 200. The mold 150 encapsulates all components between the redistribution layer 200 and the top die 110.

The top die 110, the first bottom die 120, for the second bottom die 130 and the decoupling capacitor C0, the description for the semiconductor package shown in FIG. 5 may be referred to, and repeated description is not included here again.

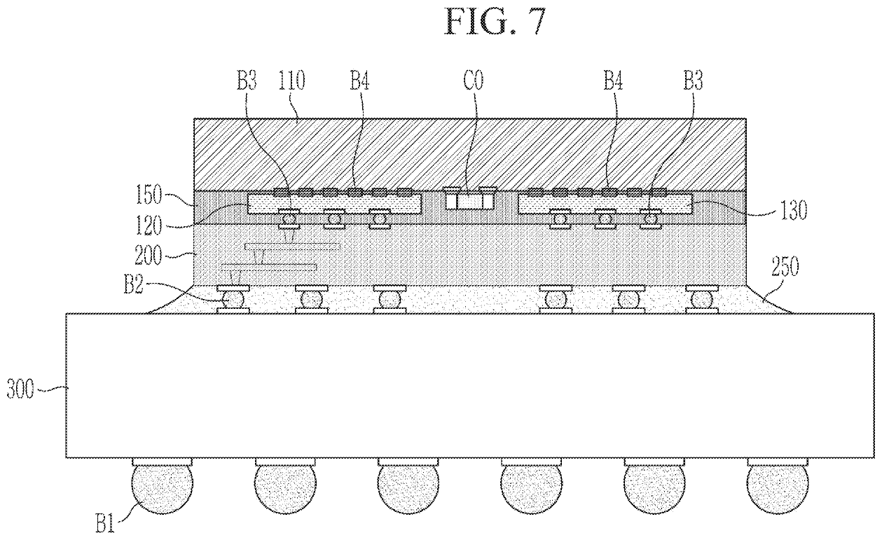

FIG. 7 is a schematic cross-sectional view of another example of a semiconductor package. FIG. 7 shows a semiconductor package having a structure in which a substrate 300 is added to the semiconductor package shown in FIG. 6.

In the present example, the semiconductor package includes the top die 110, the first bottom die 120, the second bottom die 130, the decoupling capacitor C0, the mold 150, the redistribution layer 200, and the substrate 300.

The top die 110 and the first and second bottom dies 120 and 130 are bonded to each other by the hybrid bonding B4. However, they are not limited thereto and may be bonded by solder bumps such as micro bumps.

The first and second bottom dies 120 and 130 are bonded to the redistribution layer 200 through the plurality of solder bumps B3. The redistribution layer 200 is bonded to the substrate 300 through the plurality of solder bumps B2. The plurality of solder balls B1 are disposed on the lower surface of the substrate 300.

A gap between the redistribution layer 200 and the substrate 300 is filled by an under-fill 250. The underfill 250 secures insulation of the plurality of solder bumps B2 and reinforces bonding strength between the redistribution layer 200 and the substrate 300.

Although not shown, a decoupling capacitor may be additionally provided at one or more of the various locations shown in FIG. 1.

Also, although not shown, a power network may be provided over the substrate 300, the redistribution layer 200, the first and second bottom dies 120 and 130, and the top die 110. The decoupling capacitor C0 is connected in parallel to this the power network.

The top die 110, for the first bottom die 120, the second bottom die 130, the decoupling capacitor C0, and the redistribution layer 200, the description for the semiconductor package shown in FIG. 3 may be referred to, and repeated description is not included here again.

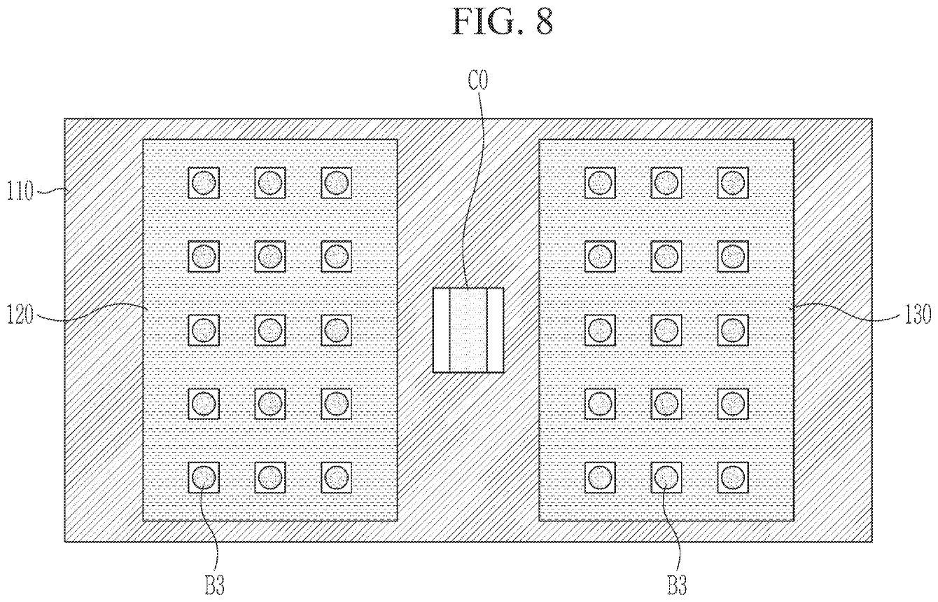

FIG. 8 is a schematic top plan view of an example of a semiconductor package.

In the present example, a structure in which the first bottom die 120 and the second bottom die 130 having a same size is attached on the lower surface of the top die 110 having a larger size is shown in a plan view.

On the lower surface of the top die 110, the first bottom die 120 and the second bottom die 130 are spaced apart from each other by a preset distance. The decoupling capacitor C0 may be attached between the first bottom die 120 and the second bottom die 130.

In the present example, the first bottom die 120 and the second bottom die 130 are spaced apart from each other to attach the decoupling capacitor C0, but are not necessarily limited thereto. In some implementations, the first bottom die 120 and the second bottom die 130 may be disposed adjacent to each other, and the decoupling capacitor C0 may be attached to an edge on the lower surface of the top die 110. That is, as long as the space for attaching the decoupling capacitor C0 is secured, the distance between the first bottom die 120 and the second bottom die 130 is not limited. Since the size of the decoupling capacitor C0 may vary, the distance between the first bottom die 120 and the second bottom die 130 may be adjusted depending on designs.

The plurality of solder bumps B3 are disposed on the lower surface of the first and second bottom dies 120 and 130. Although a limited number of solder bumps B3 are disclosed in FIG. 8 for convenience of description, but in practice, a much larger number of solder bumps B3 may be disposed.

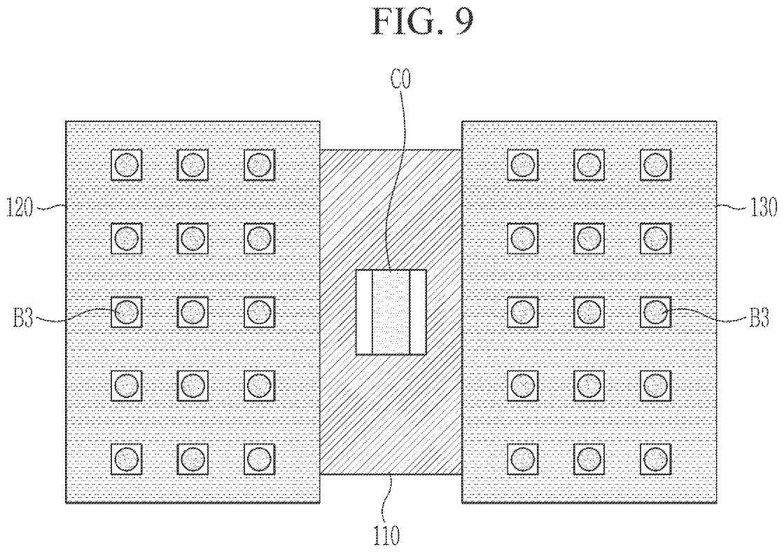

FIG. 9 is a schematic top plan view of another example of a semiconductor package.

In the present example, a structure in which the first bottom die 120 and the second bottom die 130 having a same size is attached on the lower surface of the top die 110 having a smaller size is shown in a plan view.

On the lower surface of the top die 110, the first bottom die 120 and the second bottom die 130 are spaced apart from each other by a preset distance. The decoupling capacitor C0 may be attached between the first bottom die 120 and the second bottom die 130.

In this example, the first bottom die 120 and the second bottom die 130 need to be spaced apart from each other for the attachment of the decoupling capacitor C0. Since the size of the decoupling capacitor C0 may vary, the distance between the first bottom die 120 and the second bottom die 130 may be adjusted depending on designs.

The plurality of solder bumps B3 are disposed on the lower surface of the first and second bottom dies 120 and 130. Although a limited number of solder bumps B3 are disclosed in FIG. 8 for convenience of description, but in practice, a much larger number of solder bumps B3 may be disposed.

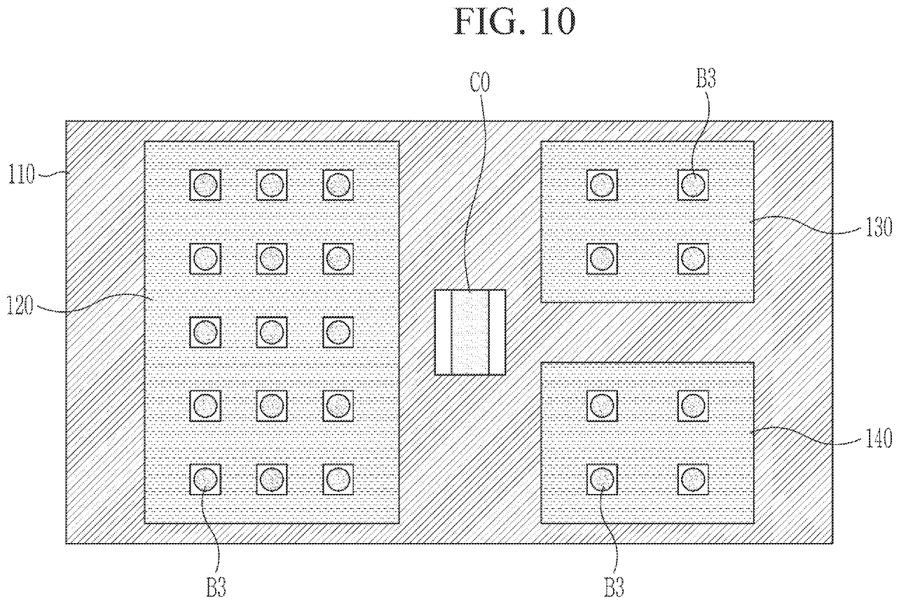

FIG. 10 is a schematic top plan view of another example of a semiconductor package.

In the present example, the first bottom die 120, the second bottom die 130 and a third bottom die 140 is attached on the lower surface of the top die 110 having a larger size is shown in a plan view.

The second bottom die 130 and the third bottom die 140 have a same size, but the first bottom die 120 has a different size than the second bottom die 130 and the third bottom die 140.

The decoupling capacitor C0 is attached to a center of the lower surface of the top die 110. The first bottom die 120 is disposed in one side of the decoupling capacitor C0, and the second bottom die 130 and the third bottom die 140 is disposed in another side of the decoupling capacitor C0.

In some implementations, first, second, and third bottom dies 120, 130, and 140 may have different sizes. In some implementations, the decoupling capacitor C0 may be disposed between the second bottom die 130 and the third bottom die 140.

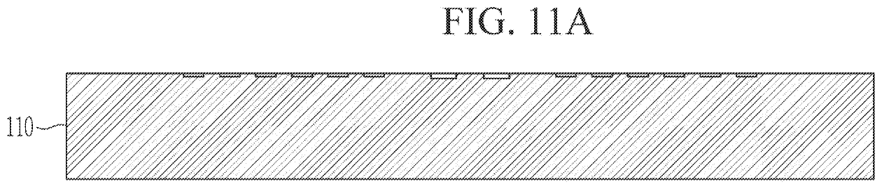

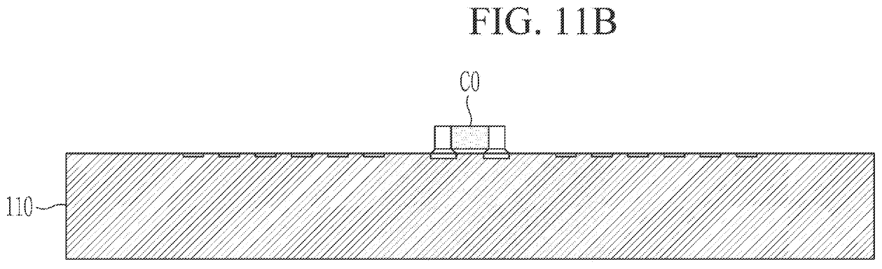

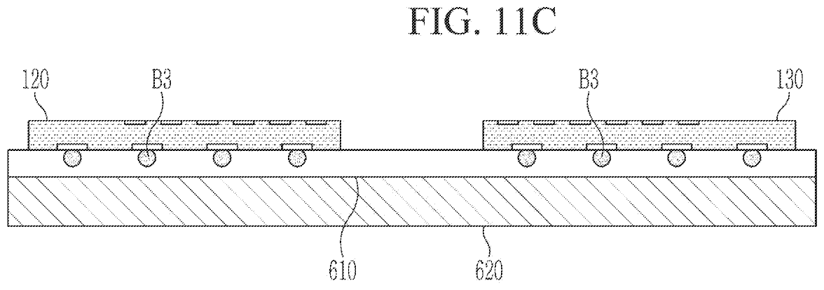

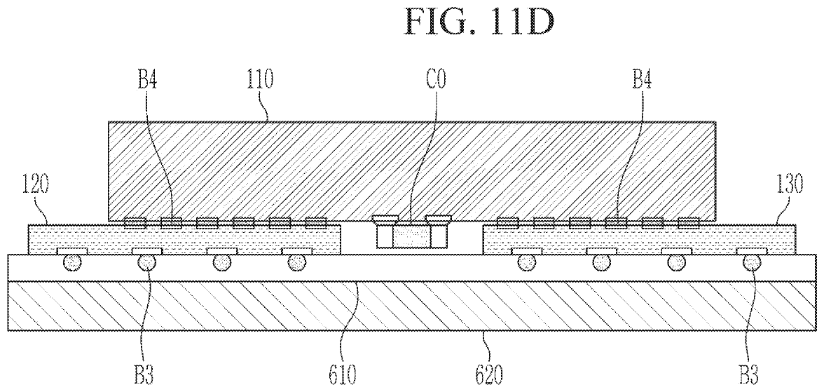

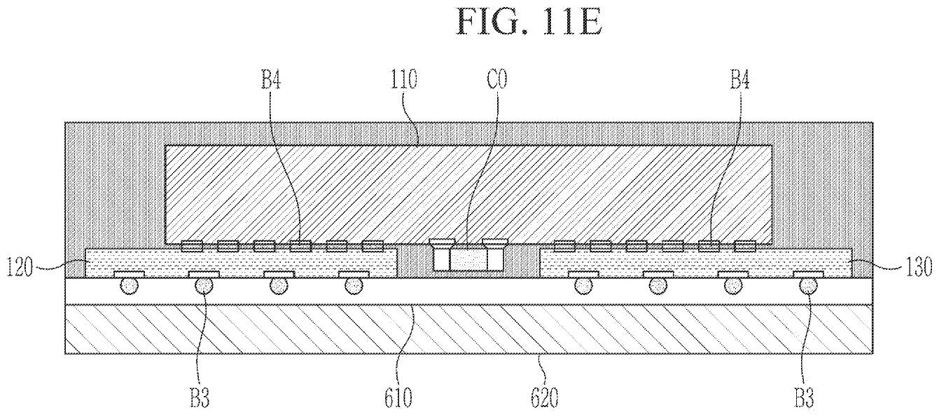

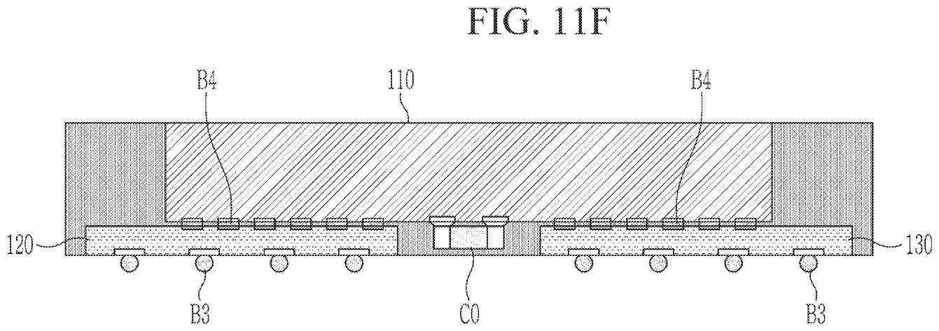

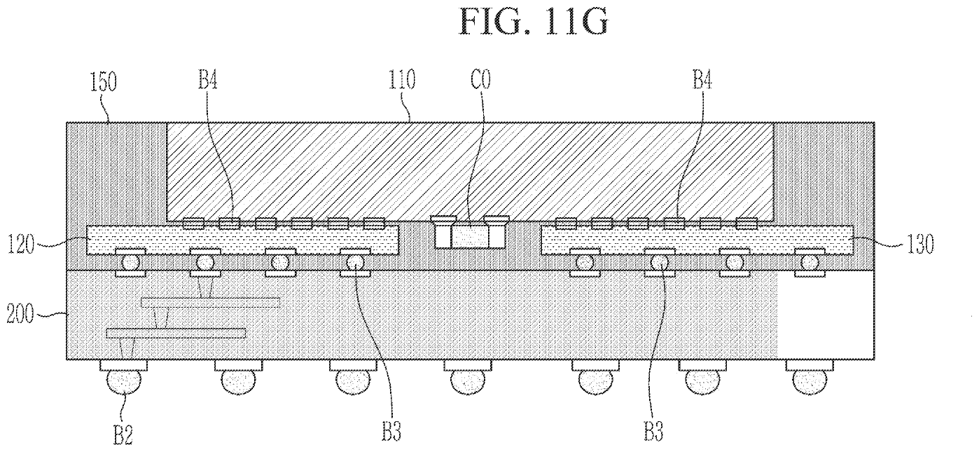

FIG. 11A to FIG. 11G show an example of a method for manufacturing a semiconductor package, respectively.

A method for manufacturing a semiconductor package in some implementations is a method for manufacturing the semiconductor package shown in FIG. 3.

In FIG. 11A, the top die 110 is prepared. The top die 110 is elevated with its lower surface facing upward. A plurality of connection pads are provided on the lower surface of the top die 110. The plurality of connection pads are conductive pads electrically connected to elements in the top die 110.

In FIG. 11B, the decoupling capacitor C0 is attached on the lower surface of the top die 110. The decoupling capacitor C0 may be attached to the center, but is not limited thereto.

When the decoupling capacitor C0 is attached to the top die 110 in the state of a wafer, a singulation process is applied to the top die 110 by a sawing process.

In FIG. 11C, the first bottom die 120 and the second bottom die 130 are spaced apart from each other by a preset distance and attached on a carrier 620 by an adhesive tape 610.

The first bottom die 120 and the second bottom die 130 includes the plurality of connection pads on their upper surfaces, and the plurality of solder bumps B3 on their lower surfaces.

In FIG. 11D, the top die 110 is turned over and bonded onto the first bottom die 120 and the second bottom die 130 by the hybrid bonding B4. The decoupling capacitor C0 is located between the first bottom die 120 and the second bottom die 130.

In FIG. 11E, the mold material is provided from the top, and thus the top die 110, the first and second bottom dies 120 and 130, and the decoupling capacitor C0 are covered by the mold material.

In FIG. 11F, the mold material is ground to expose an upper surface of the top die 110, and the carrier removed.

In FIG. 11G, the first bottom die 120 and the second bottom die 130 are bonded onto the upper surface of the redistribution layer 200 through the plurality of solder bumps B3. Then, the mold material is filled between the redistribution layer 200 and the first and second bottom dies 120 and 130 by an additional molding process. In addition, the plurality of solder bumps B2 are provided on the lower surface of the redistribution layer 200.

Through the above process, the semiconductor package shown in FIG. 3 is obtained. By bonding this semiconductor package onto the substrate through the plurality of solder bumps B2, the semiconductor package shown in FIG. 4 may be obtained.

In some implementations, the top die 110 may be a logic die, and the first and second bottom dies 120 and 130 may be input and output dies.

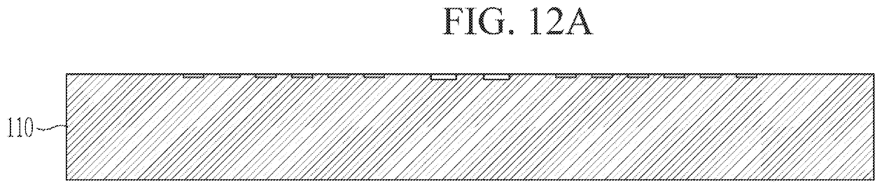

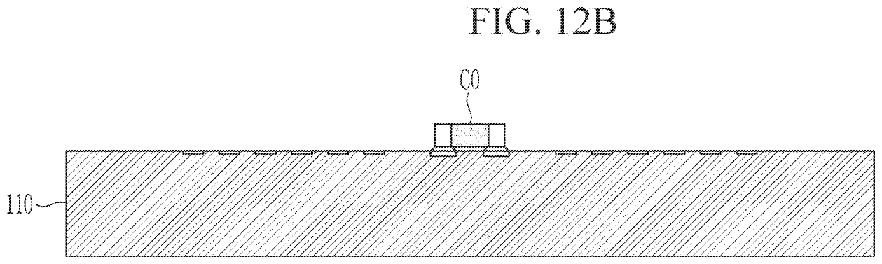

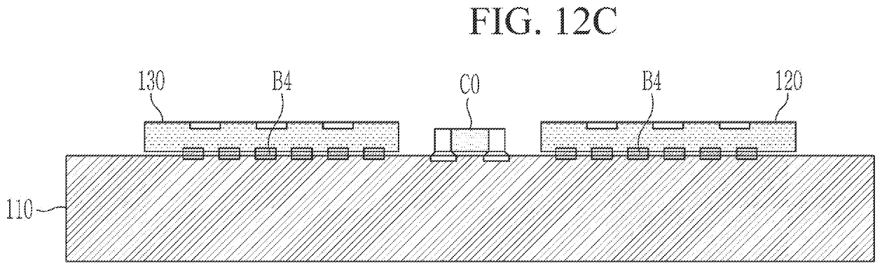

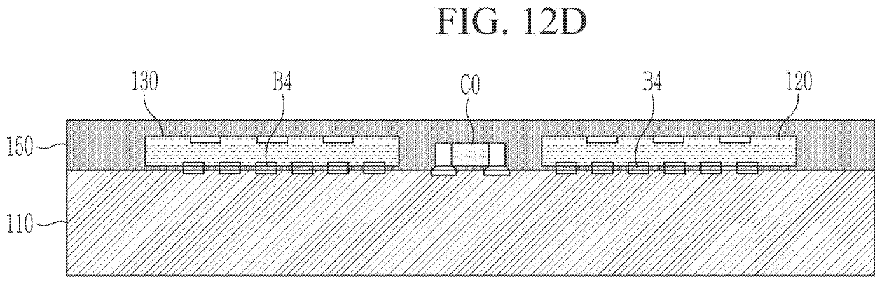

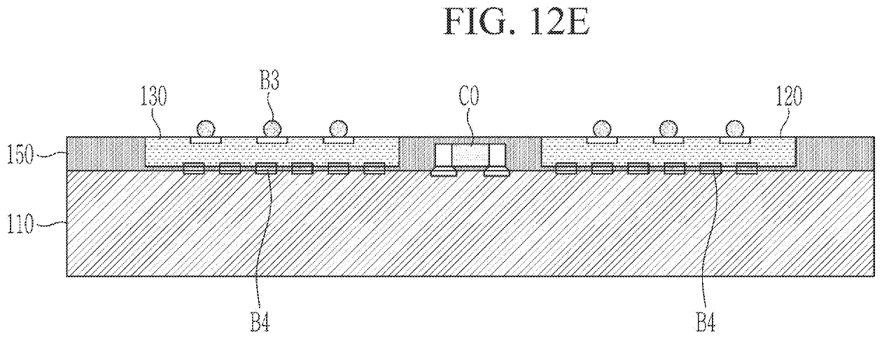

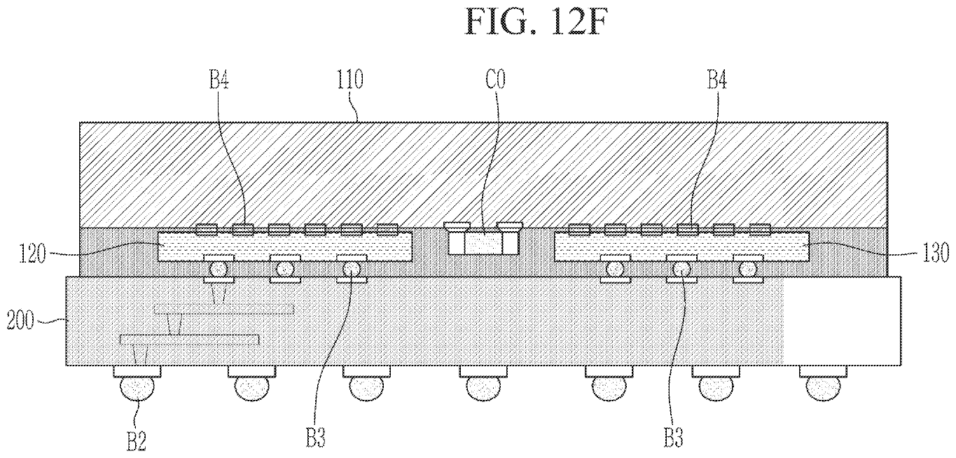

FIG. 12A to FIG. 12G show another example of a method for manufacturing a semiconductor package, respectively.

A method for manufacturing a semiconductor package in some implementations is a method for manufacturing the semiconductor package shown in FIG. 6.

In FIG. 12A, the top die 110 is prepared. The top die 110 is elevated with its lower surface facing upward. The plurality of connection pads are provided on the lower surface of the top die 110. The plurality of connection pads are conductive pads electrically connected to elements in the top die 110.

In FIG. 12B, the decoupling capacitor C0 is attached on the lower surface of the top die 110. The decoupling capacitor C0 may be attached to the center, but is not limited thereto.

In FIG. 12C, the first bottom die 120 and the second bottom die 130 bonded to the lower surface of the top die 110 by the hybrid bonding B4, in a region where the decoupling capacitor C0 is not attached.

In FIG. 12D, the mold material is provided from the top, and thus the first and second bottom dies 120 and 130 and the decoupling capacitor C0 attached on the lower surface of the top die 110 are covered by the mold material.

In FIG. 12E, the mold material is ground to expose the lower surfaces of the first and second bottom dies 120 and 130. The plurality of solder bumps B3 are provided on the lower surface of the first and second bottom dies 120 and 130.

In FIG. 12F, the first bottom die 120 and the second bottom die 130 are bonded onto the upper surface of the redistribution layer 200 through the plurality of solder bumps B3. Then, the mold material is filled between the redistribution layer 200 and the first and second bottom dies 120 and 130 by an additional molding process. In addition, the plurality of solder bumps B2 are provided on the lower surface of the redistribution layer 200.

Through the above process, the semiconductor package shown in FIG. 6 is obtained. By bonding this semiconductor package onto the substrate through the plurality of solder bumps B2, the semiconductor package shown in FIG. 7 may be obtained.

In some implementations, the top die 110 may be a logic die, and the first and second bottom dies 120 and 130 may be input and output dies.

In the foregoing implementations, for convenience, a semiconductor package having one decoupling capacitor and a method for manufacturing the same have been described. However, those skilled in the art will readily understand that two or more decoupling capacitors may be employed in the above-described implementations. Since decoupling capacitors may be manufactured in various sizes, the size and number of decoupling capacitors attached to the top die are not limited in the present disclosure, since they are merely limited by the space between the first and second bottom dies 120 and 130.

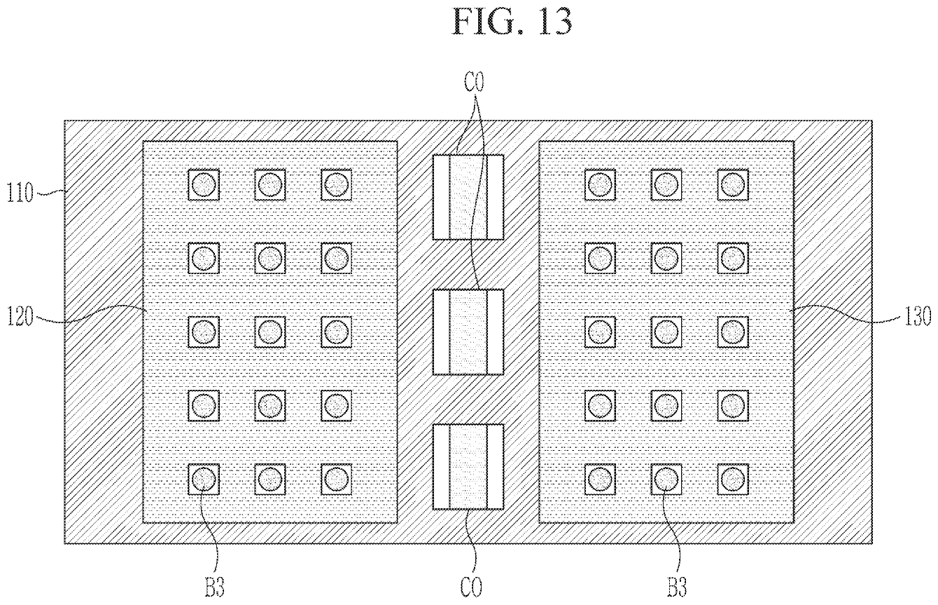

FIG. 13 is a top plan view of an example of a semiconductor package with a plurality of decoupling capacitors. Three decoupling capacitors are disposed between the first and second bottom dies 120 and 130. Two decoupling capacitors may be attached, and also, four or more decoupling capacitors may be attached.

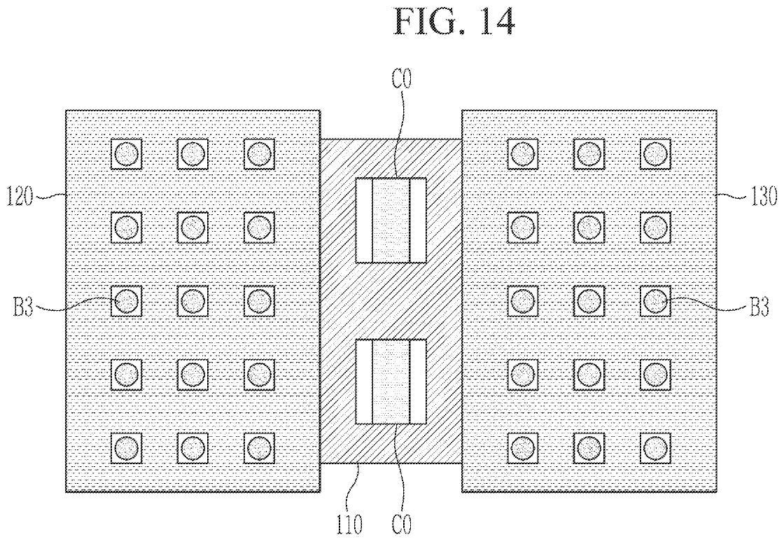

FIG. 14 is a top plan view of another example of a semiconductor package with a plurality of decoupling capacitors. Two decoupling capacitors are disposed between the first and second bottom dies 120 and 130. Three or more decoupling capacitors may be attached.

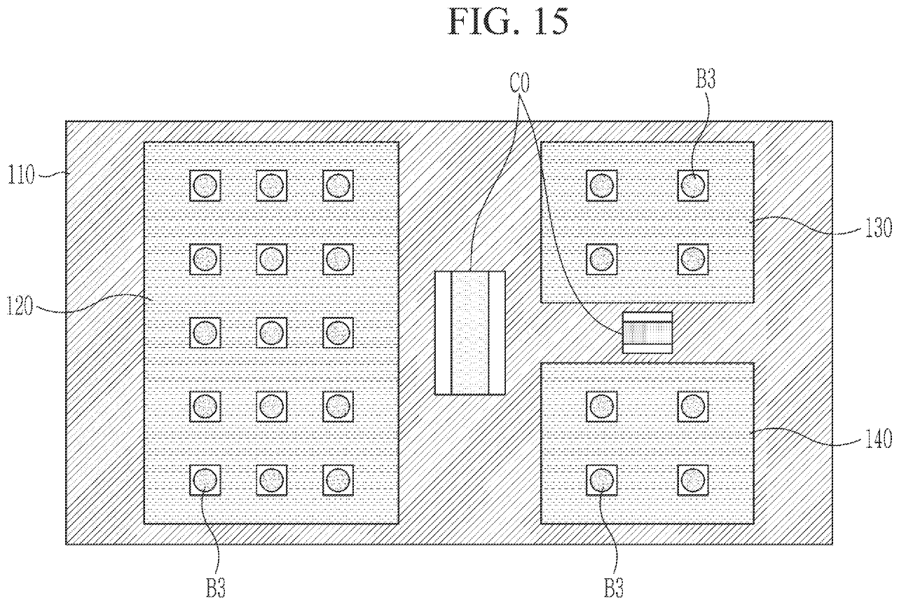

FIG. 15 is a top plan view of another example of a semiconductor package with a plurality of decoupling capacitors. The first bottom die 120, the second bottom die 130, and the third bottom die 140 are disposed on the lower surface of the top die 110, and the two decoupling capacitor C0 are disposed in a space between the bottom dies. When the space between the second bottom die 130 and the third bottom die 140 is relatively narrow, a decoupling capacitor of a relatively small size may be disposed. In addition, a decoupling capacitor disposed between the first bottom die 120 and second and third bottom dies 130 and 140 may have a rectangular shape.

In addition, a semiconductor package with a plurality of decoupling capacitors may be manufactured, by changing the step of attaching the decoupling capacitor to a step of attaching a plurality of decoupling capacitor, in the above-described implementations for a method for manufacturing a semiconductor package.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While this disclosure has been described in connection with what is presently considered to be practical implementations, it is to be understood that the disclosure is not limited to the disclosed implementations, but, on the contrary, is intended to cover various modifications and equivalent arrangements included within the spirit and scope of the appended claims.

What is claimed is:

1. A semiconductor package, comprising:
a top die;
first and second bottom dies attached on a lower surface of the top die and being apart from each other by a preset distance; and
at least one decoupling capacitor connected to the lower surface of the top die between the first bottom die and the second bottom die,
wherein the top die, the first bottom die, and the second bottom die are chiplets.

2. The semiconductor package of claim 1, wherein a portion of upper surfaces of the first bottom die and the second bottom die face the top die, and a remaining portion extends outwards on a plane of the top die.

3. The semiconductor package of claim 1, wherein entire upper surfaces of the first bottom die and the second bottom die face the top die.

4. The semiconductor package of claim 1, wherein the first bottom die and the second bottom die have a same size.

5. The semiconductor package of claim 4, wherein the at least one decoupling capacitor is disposed at a center of the top die.

6. The semiconductor package of claim 1, wherein the first bottom die and the second bottom die have different sizes.

7. The semiconductor package of claim 1, wherein the top die and the first and second bottom dies are bonded to each other by a hybrid bonding.

8. The semiconductor package of claim 1, wherein the top die and the first and second bottom dies are bonded to each other by micro bump.

9. The semiconductor package of claim 1, wherein a plurality of solder bumps are provided on lower surfaces of the first bottom die and the second bottom die.

10. The semiconductor package of claim 9, further comprising a mold configured to encapsulate the top die, the first bottom die, the second bottom die, and the at least one decoupling capacitor, wherein an upper surface of the top die and lower surfaces of the first and second bottom dies are exposed.

11. The semiconductor package of claim 9, further comprising a redistribution layer bonded to the first bottom die and the second bottom die through the plurality of solder bumps.

12. The semiconductor package of claim 11, further comprising a mold encapsulate all elements on an upper surface of the redistribution layer.

13. The semiconductor package of claim 12, further comprising a substrate bonded to a lower surface of the redistribution layer through the plurality of solder bumps,
wherein a plurality of solder balls are provided on a lower surface of the substrate, and
wherein an under-fill is filled between the redistribution layer and the substrate.

14. The semiconductor package of claim 13, wherein:
a power network is established across the substrate, the redistribution layer, the first and second bottom dies, and the top die; and
the at least one decoupling capacitor is connected in parallel to the power network.

15. The semiconductor package of claim 1, further comprising a third bottom die attached to the lower surface of the top die.

16. The semiconductor package of claim 1, wherein the top die is a logic die, and the first and second bottom dies are input and output dies.

17. A method for manufacturing a semiconductor package, comprising:
attaching at least one decoupling capacitor on a lower surface of a top die;
attaching a first bottom die and a second bottom die having a plurality of solder bumps on lower surfaces onto a carrier, wherein the first bottom die and the second bottom die are spaced apart from each other with a preset gap;
attaching the top die on upper surfaces of the first and second bottom dies by a hybrid bonding such that the at least one decoupling capacitor is positioned in the gap between the first bottom die and the second bottom die;
sealing all components on the carrier by a mold material; and
grinding the mold material to expose a surface of the top die and removing the carrier,
wherein the top die, the first bottom die, and the second bottom die are chiplets, and
wherein a portion of upper surfaces of the first bottom die and the second bottom die face the top die and a remaining portion extends outwards on a plane of the top die.

18. The method of claim 17, further comprising:
attaching the semiconductor package on an upper surface of a redistribution layer through the plurality of solder bumps;
additionally providing the mold material between the first and second bottom dies and the redistribution layer; and
providing the plurality of solder bumps on a lower surface of the redistribution layer.

19. A method for manufacturing a semiconductor package, comprising:
attaching at least one decoupling capacitor on a lower surface of a top die;
attaching upper surfaces of a first bottom die and a second bottom die on the lower surface of the top die by a hybrid bonding, wherein the at least one decoupling capacitor is positioned between the first bottom die and the second bottom die;
sealing all components on the lower surface of the top die by a mold material; and
grinding the mold material to expose lower surfaces of the first bottom die and the second bottom die; and
providing a plurality of solder bumps on the lower surfaces of the first bottom die and the second bottom die,
wherein the top die, the first bottom die, and the second bottom die are chiplets, and
wherein entire upper surfaces of the first bottom die and the second bottom die face the top die.

20. The method of claim 19, further comprising:
attaching the semiconductor package on an upper surface of a redistribution layer through the plurality of solder bumps of first and second bottom dies;
additionally providing the mold material between the first and second bottom dies and the redistribution layer; and
providing the plurality of solder bumps on a lower surface of the redistribution layer.
